(19) United States
(12) Patent Application Publication
(10) Pub. No.: US 2015/0027374 A1
(43) Pub. Date: Jan. 29, 2015

(54) VAPOR DEPOSITION APPARATUS

(71) Applicant: Samsung Display Co., Ltd., Yongin-City (KR)

(72) Inventors: Jin-Kwang Kim, Yongin-City (KR); Seung-Yong Song, Yongin-City (KR); Myung-Soo Huh, Yongin-City (KR); Suk-Won Jung, Yongin-City (KR); Choel-Min Jang, Yongin-City (KR); Jae-Hyun Kim, Yongin-City (KR); Sung-Chul Kim, Yongin-City (KR)

(21) Appl. No.: 14/302,646

(22) Filed: Jun. 12, 2014

(30) Foreign Application Priority Data
Jul. 25, 2013 (KR) 10-2013-0088263

(51) Int. Cl. C23C 16/44; C23C 16/455; C23C 16/50

(52) U.S. Cl. CPC C23C 16/4412; C23C 16/50; C23C 16/4408; C23C 16/455
USPC 118/723 R; 118/722; 137/544

(57) ABSTRACT

A vapor deposition apparatus includes a first injection unit through which a first raw gas is injected in a first direction, and a first filter unit which is mounted in the first injection unit and includes a plurality of plates separated from one another in the first direction and disposed in parallel to one another, where holes are defined in each of the plurality of plates which is detachably coupled in the first filter unit.

This application claims priority to Korean Patent Application No. 10-2013-0088263, filed on Jul. 25, 2013, and all the benefits accruing therefrom under 35 U.S.C. §119, the disclosure of which is incorporated herein in its entirety by reference.

### BACKGROUND

1. Field

One or more exemplary embodiments of the invention relate to a vapor deposition apparatus.

2. Description of the Related Art

Semiconductor devices, display apparatuses and various other electronic devices generally include a plurality of thin films. There are various methods of forming such thin films. One of the various methods is a vapor deposition method, for example.

The vapor deposition method uses one or more gases as a raw material for forming thin films. Such a vapor deposition method includes chemical vapor deposition (“CVD”), atomic layer deposition (“ALD”) and various other methods.

Among the various vapor deposition methods, in ALD, one raw material is injected onto a substrate and then purged and pumped to absorb a single molecular layer or more layers, and then another raw material is injected onto the substrate and then purged and pumped to finally form a desired single atomic layer or a plurality of atomic layers.

Among display apparatuses, organic light-emitting display apparatus has not only wide viewing angles and excellent contrast but also rapid response times, and thus, is attracting attention as next generation display apparatus.

The organic light-emitting display apparatus generally includes an intermediate layer including an organic emission layer between a first electrode and a second electrode facing each other and one or more various thin films in addition thereto. In this case, deposition processes may be used to form thin films of the organic light-emitting display apparatus.

### SUMMARY

However, as organic light-emitting display apparatus has become larger and high resolution is necessary, it is difficult to deposit large-sized thin films with desired properties. Also, there is a limitation to improve the efficiency of processes of forming such thin films.

One or more embodiments of the invention include a vapor deposition apparatus that is capable of improving deposition layer properties and is easily maintained and repaired.

Additional exemplary embodiments will be set forth in part in the description which follows and, in part, will be apparent from the description, or may be learned by practice of the exemplary embodiments.

According to one or more exemplary embodiments of the invention, a vapor deposition apparatus includes a first injection unit through which a first raw gas is injected in a first direction and a first filter unit which is mounted in the first injection unit and includes a plurality of plates separated from one another in the first direction and disposed in parallel to one another where holes are defined in each of the plurality of plates which is detachably coupled with the first filter unit.

In an exemplary embodiment, a numbers of the holes defined in the plurality of plates may increase in the first direction.

In an exemplary embodiment, a size of the holes defined in the plurality of plates may decrease in the first direction.

In an exemplary embodiment, the vapor deposition apparatus may further include a second injection unit through which a second raw gas is injected in the first direction. In this case, a plasma generator may be disposed in a plasma generation part of the second injection unit, a corresponding surface of a body of the vapor deposition apparatus surrounds the plasma generator, and a plasma generation space is provided between the plasma generator and the corresponding surface.

In an exemplary embodiment, the vapor deposition apparatus may further include an exhaust unit located between the first injection unit and the second injection unit. The first filter unit may be mounted in the exhaust unit.

In an exemplary embodiment, the first injection unit and the exhaust unit may have the same configuration.

In an exemplary embodiment, the vapor deposition apparatus may further include a supply part supplying the second raw gas to the plasma generation space. A second filter unit may be mounted on the second injection unit.

In an exemplary embodiment, the first filter unit and the second filter unit may have the same configuration.

In an exemplary embodiment, the vapor deposition apparatus may further include a purge unit between the first injection unit and the second injection unit.

According to one or more exemplary embodiments of the invention, a vapor deposition apparatus for providing a deposition film on a substrate includes a first injection unit through which a first raw gas is injected in a first direction toward the substrate, a purge unit through which a purge gas is injected in the first direction, and an exhaust unit through which an exhaust gas is discharged in a second direction opposite the first direction. In this case, first filter units are respectively mounted in the first injection unit and the exhaust unit, and the first injection unit and the exhaust unit have the same configuration.

In an exemplary embodiment, each of the first filter units may include a plurality of plates disposed in the first direction in parallel to one another. Holes may be defined in each of the plurality of plates.

In an exemplary embodiment, the plurality of plates may be arranged to be separated from one another, and a number of the holes defined in the plurality of plates may increase in the first direction.

In an exemplary embodiment, the number of the holes defined in the plurality of plates may increase two or three times in the first direction.

In an exemplary embodiment, a size of the holes defined in the plurality of plates may decrease in the first direction.

In an exemplary embodiment, each of the plurality of plates may be detachably coupled with each of the first filter units.

In an exemplary embodiment, the vapor deposition apparatus may include a second injection unit injecting a second raw gas into the second direction, where the purge unit and the exhaust unit may be disposed between the first injection unit and the second injection unit.

In an exemplary embodiment, the second injection unit may further include a plasma generation part including a plasma generator, a corresponding surface surrounding the plasma generator, and a plasma generation space provided between the plasma generator and the corresponding surface.

In an exemplary embodiment, the vapor deposition apparatus may further include a supply part supplying the second raw gas to the plasma generation space. A second filter unit may be mounted on the second injection unit.

In an exemplary embodiment, each of the first filter units and the second filter unit may have the same configuration.

In an exemplary embodiment, the substrate and the vapor deposition apparatus may be provided to move relative to each other.

### BRIEF DESCRIPTION OF THE DRAWINGS

These and/or other exemplary embodiments will become apparent and more readily appreciated from the following description of the exemplary embodiments, taken in conjunction with the accompanying drawings of which:

FIG. 1 is a schematic cross-sectional view illustrating an exemplary embodiment of a vapor deposition apparatus according to the invention;

FIG. 2 is a cross-sectional view illustrating a part taken along line V-V shown in FIG. 1;

FIG. 3 is a perspective view illustrating a filter unit of FIG. 1;

FIG. 4 is a cross-sectional view illustrating another exemplary embodiment of the vapor deposition according to the invention;

FIG. 5 is a schematic cross-sectional view illustrating an organic light-emitting display apparatus manufactured by using the vapor deposition apparatus of FIG. 1; and

FIG. 6 is an enlarged view illustrating a part F shown in FIG. 5.

### DETAILED DESCRIPTION

Reference will now be made in detail to exemplary embodiments, which are illustrated in the accompanying drawings, where like reference numerals refer to the like elements throughout. In this regard, the exemplary embodiments may have different forms and should not be construed as being limited to the descriptions set forth herein. Accordingly, the exemplary embodiments are merely described below, by referring to the figures, to explain exemplary embodiments of the description.

Since the invention may have various modifications and several exemplary embodiments, exemplary embodiments are shown in the drawings and will be described in detail. However, this is not to limit the invention to the exemplary embodiments but should be understood as including all modifications, equivalents, and substitutes included in the spirit and the scope of the invention. While describing the invention, when it is determined that a detailed description of well-known typical art may make the points of the invention unclear, the detailed description will be omitted.

It will be understood that although the terms “first”, “second”, etc. may be used herein to describe various components, these components should not be limited by these terms. These terms are only used to distinguish one component from another.

It will be understood that when a layer, film, region, or plate is referred to as being “disposed/formed on,” another layer, film, region, or plate, it can be directly or indirectly defined/formed on the other layer, film, region, or plate. That is, for example, intervening layers, films, regions, or plates may be present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the invention will be described in detail with reference to the attached drawings, in which like reference numerals designate like elements and repetitive explanation thereof will be omitted. In the drawings, thicknesses of several layers and regions are enlarged to clearly illustrate them. Also, for convenience of description, thicknesses of some layers and regions are exaggerated.

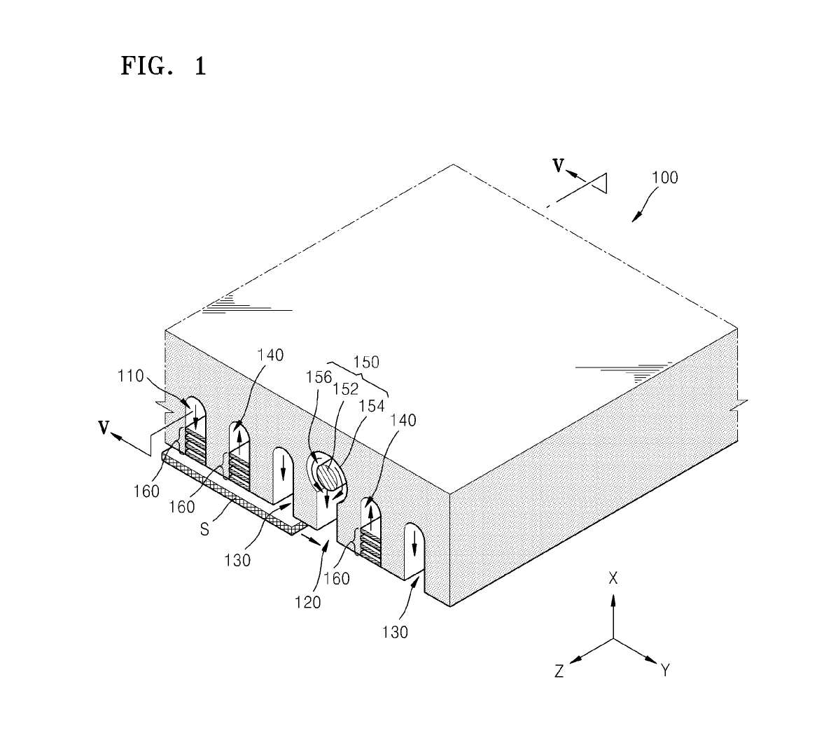

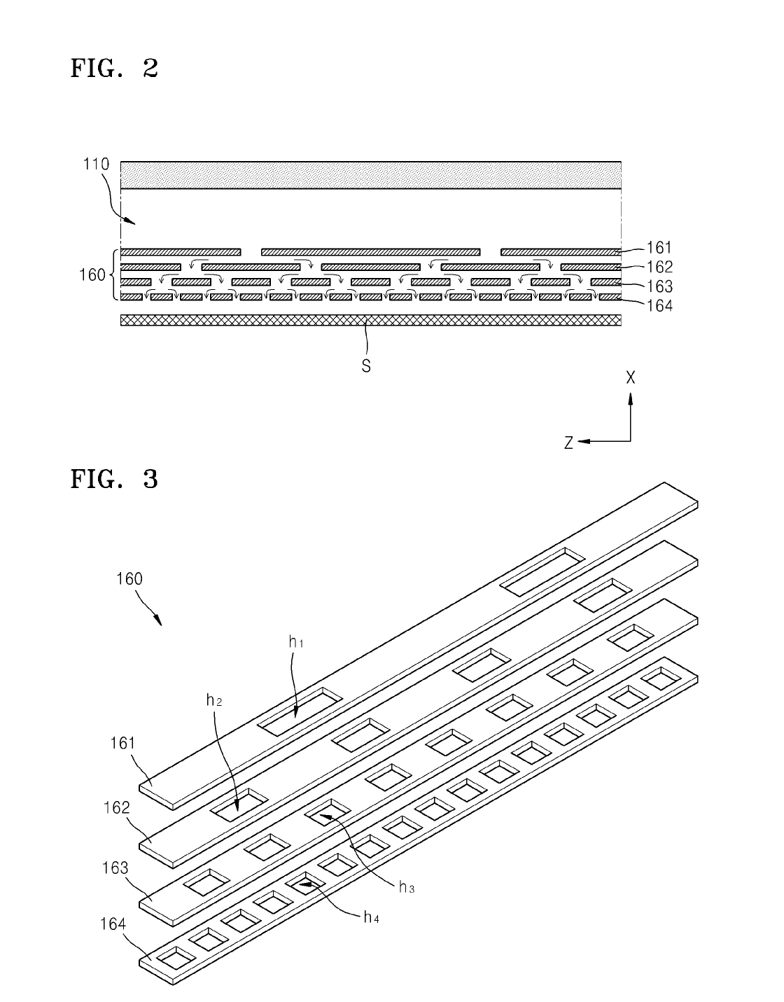

FIG. 1 is a schematic cross-sectional view illustrating a vapor deposition apparatus 100 according to an exemplary embodiment of the invention, FIG. 2 is a cross-sectional view illustrating a part V-V of FIG. 1, and FIG. 3 is a perspective view illustrating a filter unit of FIG. 1.

Referring to FIGS. 1 to 3, the vapor deposition apparatus 100 may include a first injection unit 110 injecting a first raw gas in a first direction along X axis, the first direction being a substrate direction, and a second injection unit 120 injecting a second raw gas in the first direction. The first injection unit 110 and the second injection unit 120 may be separated from each other. Also, the vapor deposition apparatus 100 may further include a purge unit 130 and an exhaust unit 140 located between the first injection unit 110 and the second injection unit 120.

The vapor deposition apparatus 100 may include a body in which the first and second injection units 110 and 120 are defined. The first and second injection units 110 and 120 may define flow paths through which the first and second raw gases flow in the body, to outside the body. The first and second injection units 110 and 120 may be exposed to the outside of the body. As illustrated in FIG. 1 and FIG. 2, openings may be defined in a lower surface of the body facing the substrate S, so as to expose the first and second injection units 110 and 120 to the outside of the body. The first and second injection units 110 and 120 may be recessed from the lower surface of the body, but the invention is not limited thereto.

A first filter unit 160 may be mounted on the first injection unit 110. The first filter unit 160 may be mounted on an end portion of the first injection unit 110 and may allow the first raw gas injected by the first injection unit 110 to be evenly injected onto the substrate S.

In an exemplary embodiment, the first filter unit 160 may include a plurality of plates 161 to 164, which may be disposed in parallel to one another in the first direction. Also, the plurality of plates 161 to 164 are arranged to be separated from one another, and holes h1 to h4 through which the first raw gas passes may be defined in the plurality of plates 161 to 164, respectively. Thereby, the first filter unit 160 may allow the first raw gas to be uniformly injected onto the substrate S by controlling a transfer path of the first raw gas while the first raw gas is transferred in the first direction.

Hereinafter, referring to FIGS. 2 and 3, the first filter unit 160 will be described in detail. As shown in FIGS. 2 and 3, the first filter unit 160 includes the first plate 161, the second plate 162, the third plate 163 and the fourth plate 164 sequentially disposed in the first direction. However, the invention is not limited thereto. That is, the first filter unit 160 may include more or less plates in order to allow the first raw gas to be uniformly injected onto the substrate S.

Referring to FIGS. 2 and 3, the first plate 161 may be located farthest from the substrate S and the fourth plate 164 may be located nearest to the substrate S.

Comparing the first plate 161 with the second plate 162, a number of the second holes h2 defined in the second plate 162 disposed nearer the substrate S than the first plate 161 in the first direction may be larger than a number of the first holes h1 defined in the first plate 161. In an exemplary embodiment, the number of the second holes h2 may be two or three times as large as the number of the first holes h1.

To allow the first raw gas passing through the first holes h1 to arrive at the second holes h2 with a uniform mean transfer distance, the first holes h1 may be located in center portions between the second holes h2 defined in the periphery thereof, respectively.

In an exemplary embodiment, as shown in FIGS. 2 and 3, when the number of the second holes h2 is two times as large as the number of the first holes h1, one of the first holes h1 may be located on the middle point of a line between two second holes h2. Also, when the number of the second holes h2 is three times as large as the number of the first holes h1, three adjacent second holes h2 define an equilateral triangle and the first hole h1 may be located at a center of the equilateral triangle provided by the second holes h2.

Also, to allow a larger amount of the first raw gas to pass through the holes, a size of the first hole h1 may be larger than that of the second hole h2.

When the first holes h1 and the second holes h2 are defined as described above, the first raw gas may evenly widely spread in the first filter unit 160.

Similarly, a number of the third holes h3 defined in the third plate 163 disposed nearer to the substrate S than the second plate 162 in the first direction may be larger than the number of the second holes h2 defined in the second plate 162 and a number of the fourth holes h4 defined in the fourth plate 164 may be larger than the number of the third holes h3.

Also, to allow the first raw gas to evenly spread with a uniform mean transfer distance, the respective second holes h2 may be located in center portions between the third holes h3 defined in the periphery thereof and the respective third holes h3 may be located in center portions between the fourth holes h4 defined in the periphery thereof. Also, in the first direction, sizes of holes h2 to h4 may be smaller in an order from the second holes h2 to the fourth holes h4, respectively.

Accordingly, when transferred toward the substrate S, the first raw gas is evenly dispersed overall the first filter unit 160 in such a way that the first raw gas may be uniformly injected onto the substrate S, thereby easily improving properties of a thin film disposed on the substrate S.

Also, since the first raw gas may arrive at the fourth holes h4 along the uniform mean transfer distance, there is no pressure difference among the fourth holes h4 through which the first raw gas is finally injected. Accordingly, the invention may be applied to a case where condensation of the first raw gas caused by the hole pressure is of concern.

Also, while the first raw gas is being transferred, impurities such as particles included in the first raw gas may be filtered by the plurality of plates 161 to 164.

In FIGS. 2 and 3, the numbers of the first to fourth holes h1 to h4 defined in the first to fourth plates 161 to 164 respectively double from the first plate 161 to the fourth plate 164, but the invention is not limited thereto. In an exemplary embodiment, the numbers of the first to fourth holes h1 to h4 defined in the first to fourth plates 161 to 164 may increase by three, four, or N times or may increase irregularly in an order from the first plate 161 to the fourth plate 164.

The plurality of plates 161 to 164 may include a material having excellent corrosion resistance and each of the plurality of plates 161 to 164 may be detachably coupled with the first filter unit 160. Accordingly, the plurality of plates 161 to 164 may be periodically replaced, thereby it is possible to easily remove particles filtered by the plurality of plates 161 to 164. Accordingly, it may be easy to maintain and repair the vapor deposition apparatus 100.

Referring to FIG. 1, a plasma generation part 150 is in the second injection unit 120. The plasma generation part 150 may include a plasma generator 152, a corresponding surface 154 of the body of the vapor deposition apparatus 100 surrounds the plasma generator 152, and a plasma generation space 156 is provided between the plasma generator 152 and the corresponding surface 154.

The plasma generator 152 may include an electrode having a round bar shape, and the corresponding surface 154 may include a grounded electrode. A voltage is applied to the plasma generator 152. However, the invention is not limited thereto and the plasma generator 152 may be grounded, and a voltage may be applied to the corresponding surface 154. When generating an electric potential difference between the plasma generator 152 and the corresponding surface 154 described above, plasma may be generated in the plasma generation space 156 and the second raw gas may be changed into radicals in the plasma generation space 156.

As shown in FIG. 1, the vapor deposition apparatus 100 includes one first injection unit 110 and one second injection unit 120 however the invention is not limited thereto. That is, in another exemplary embodiment, the vapor deposition apparatus 100 may include a plurality of first injection units 110 and a plurality of second injection units 120. In this case, the plurality of first injection units 110 and the plurality of second injection units 120 may be alternately disposed.

The purge unit 130 is located subsequent to the first injection unit 110 and the second injection unit 120 based on a transfer direction along Y axis of the substrate S and injects a purge gas in the first direction. The purge gas may be a gas having no deposition effect, for example, argon or nitrogen gas. When the purge gas is injected onto the substrate S by the purge unit 130, extra gases of the first raw gas and the second raw gas, which are not used for forming a thin film, and by-products provided during a deposition process may be physically separated from the substrate S.

The exhaust unit 140 is located subsequent to the first injection unit 110 and the second injection unit 120, respectively, based on the transfer direction of the substrate S and exhausts the by-products and an extra gas separated from the substrate S in a second direction opposite the first direction.

The first filter unit 160 may be mounted on the exhaust unit 140. Accordingly, the exhaust unit 140 and the first injection unit 110 may have the same configuration. Accordingly, an entire configuration of the vapor deposition apparatus 100 may be simplified.

When the exhaust unit 140 operates, an exhaust gas is transferred in the second direction opposite the first direction. However, since the holes h1 to h4 as described above are defined in the plurality of plates 161 to 164 included in the first filter unit 160, the exhaust gas may also be sucked while traveling along the uniform mean transfer distance. Accordingly, it is possible to perform uniform suction of the exhaust gas.

Particularly, raw gases among the exhaust gas may be deposited on a side wall of the exhaust unit 140. The first filter unit 160 is mounted on an end portion of the exhaust unit 140 in such a way that the plurality of plates 161 to 164 functions as anti-deposition plates, thereby effectively preventing the raw gases from being deposited on the side wall of the exhaust unit 140. Also, since each of the plurality of plates 161 to 164 may be detachably coupled in the first filter unit 160, it is possible to replace the plurality of plates 161 to 164. Also, since a thin film disposed on the plurality of plates 161 to 164 may be easily removed, it may be easy to maintain and repair the vapor deposition apparatus 100.

Hereinafter, referring to FIG. 1, a method of disposing a thin film on the substrate S will be briefly described. The following description refers to a case where the thin film includes AlxOy while the substrate S is being transferred in one direction.

The substrate S, on which deposition is performed, is disposed to correspond to the first injection unit 110, and then, the first injection unit 110 injects the first raw gas in the first direction. In this case, the first raw gas may be uniformly injected onto the substrate S while passing through the first filter unit 160.

In an exemplary embodiment, the first raw gas may be a gas including Al atoms, for example, gaseous trimethyl aluminum (“TMA”). Thus, an adsorption layer including Al is disposed on a top surface of the substrate S, where the adsorption layer may include a chemical adsorption layer and a physical adsorption layer.

Regarding the adsorption layer disposed on the top surface of the substrate S, the physical adsorption layer has a low binding molecular force between molecules, and thus, is separated from the substrate S by the purge gas injected by the purge unit 130 located subsequent to the first injection unit 110 according to the transfer direction of the substrate S. Also, the physical adsorption layer separated from the substrate S may be effectively removed from the substrate S by pumping of the exhaust unit 140 located subsequent to the first injection unit 110 according to the transfer direction of the substrate S. In this case, since the first filter unit 160 is mounted on the exhaust unit 140, the physical adsorption layer may be uniformly removed from the substrate S.

When the substrate S is disposed to correspond to the second injection unit 120, the second raw gas is injected in the first direction through the second injection unit 120. The second raw gas may include radicals. In an exemplary embodiment, the second raw gas may include oxygen radicals. In an exemplary embodiment, the oxygen radicals may be provided by injecting H₂O, O₂, N₂O, etc. into the plasma generation part 150 described below. The second raw gas may react with the chemical adsorption layer provided by the first raw gas previously adsorbed onto the substrate S or may substitute a part of the chemical adsorption layer, thereby finally forming a desired deposition layer, for example, an AlxOy layer. However, an excess of the second raw gas may form the physical adsorption layer and may remain on the substrate S.

The physical adsorption layer of the second raw gas that remains on the substrate S may be separated from the substrate S by the purge gas injected by the purge unit 130 located subsequent to the second injection unit 120 according to the transfer direction of the substrate S and may be uniformly removed from the substrate S by pumping of the exhaust unit 140. The first filter unit 160 mounted on the exhaust unit 140. Accordingly, while the substrate S is passing through a bottom area of the vapor deposition apparatus 100, a desired single atomic layer may be uniformly disposed on the substrate S.

As shown in FIG. 1, the substrate S is transferred in one direction, that is, the substrate S and the vapor deposition apparatus 100 move relative to each other to perform a deposition process. However, the invention is not limited thereto. In exemplary embodiments, during the deposition process, the substrate S may reciprocate below the vapor deposition apparatus 100 or the substrate S may be fixed and the vapor deposition apparatus 100 may be transferred to continuously perform deposition processes.

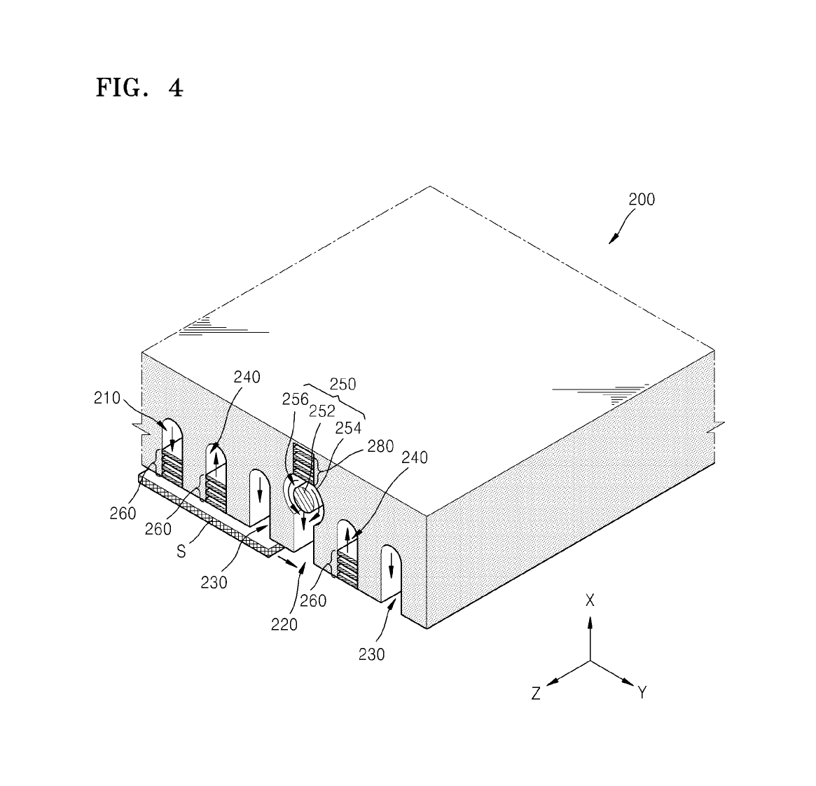

FIG. 4 is a cross-sectional view illustrating another exemplary embodiment of the vapor deposition apparatus according to the invention.

A vapor deposition apparatus 200 shown in FIG. 4 may include a first injection unit 210, a purge unit 230, an exhaust unit 240, and a second injection unit 220.

A first filter unit 260 may be mounted on end portions of the first injection unit 210 and the exhaust unit 240. Also, the second injection unit 220 may include a plasma generation part 250 including a plasma generator 252, a corresponding surface 254 surrounding the plasma generator 252, and a plasma generation space 256 provided between the plasma generator 252 and the corresponding surface 254.

The first injection unit 210, the second injection unit 220, the purge unit 230, the exhaust unit 240, the plasma generation part 250, and the first filter unit 260 are respectively similar or identical to the first injection unit 110, the second injection unit 120, the purge unit 130, the exhaust unit 140, the plasma generation part 150, and the first filter unit 160 illustrated in FIGS. 1 and 3.

Referring to FIG. 4, the vapor deposition apparatus 200 may further include a supply part supplying a second raw gas to the plasma generation space 256. A second filter unit 280 may be mounted on the supply part.

The supply part may have a penetration hole to receive the second raw gas from an external tank (not shown) and to transfer the second raw gas to the plasma generation space 256, but the invention is not limited thereto. Also, a number of supply parts may be determined according to a size of the substrate S on which a deposition process will be performed.

The second filter unit 280 may have same configuration as the first filter unit 160 illustrated in FIGS. 2 and 3. That is, the second filter unit 280 may include a plurality of plates disposed to be parallel to one another in a first direction, holes are defined in each of the plurality of plates to allow the second raw gas to pass therethrough.

Accordingly, the second raw gas may be uniformly supplied to the plasma generation space 256 in a longitudinal direction along X axis of the plasma generation space 256. Also, since it is possible to inject the second raw gas at a low pressure into the plasma generation space 256, the second raw gas may be changed into radical form more effectively, thereby improving the deposition efficiency of the vapor deposition apparatus 200.

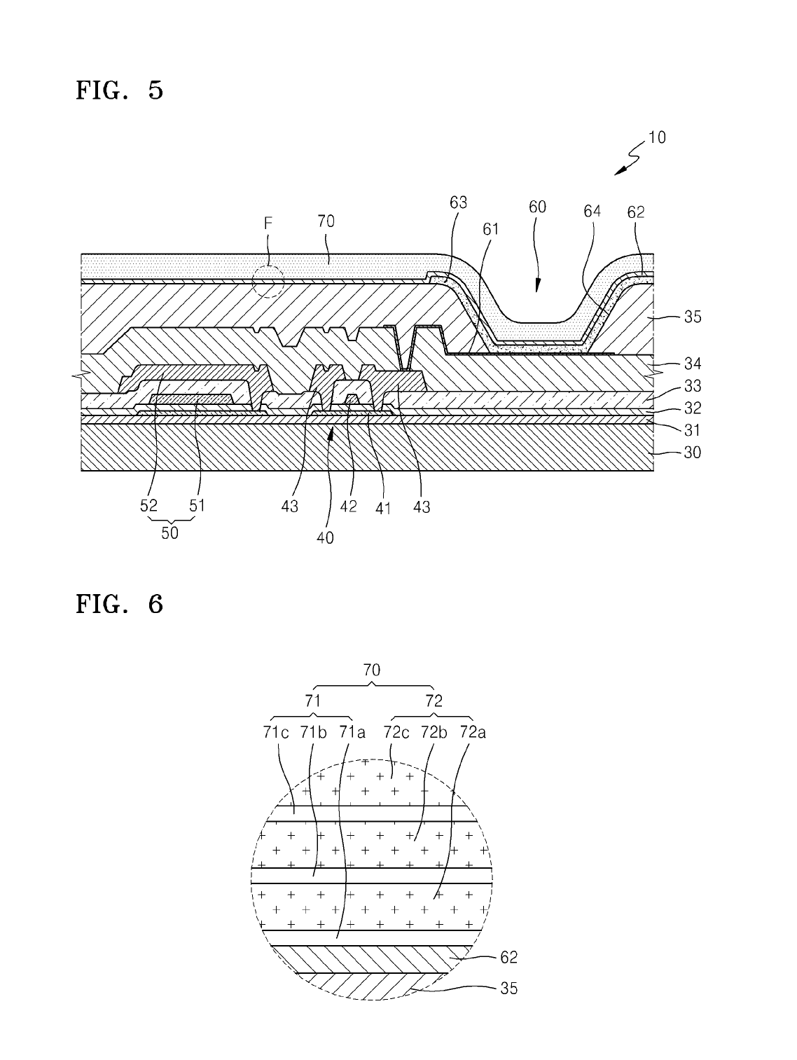

FIG. 5 is a schematic cross-sectional view illustrating an organic light-emitting display apparatus 10 manufactured by using the vapor deposition apparatus 100, and FIG. 6 is an enlarged view illustrating a part F shown in FIG. 5.

The organic light emitting display apparatus 10 is disposed on a substrate 30. In an exemplary embodiment, the substrate 30 may include one of a glass material, a plastic material and a metallic material, for example.

The substrate 30 has a top flat surface, and a buffer layer 31 including an insulating material to effectively prevent penetration of water and foreign bodies in the substrate 30 is provided in a substrate direction on the substrate 30.

A thin film transistor (“TFT”) 40, a capacitor 50 and an organic light-emitting device (“OLED”) 60 are disposed on the buffer layer 31. The TFT 40 includes an active layer 41, a gate electrode 42, and source/drain electrodes 43. The OLED 60 includes a first electrode 61, a second electrode 62 and an intermediate layer 63.

The capacitor 50 includes a first capacitor electrode 51 and a second capacitor electrode 52.

In detail, the active layer 41 is provided in a certain pattern on a top surface of the buffer layer 31. The active layer 41 may include one of an inorganic semiconductor material such as silicon, an organic semiconductor material and an oxide semiconductor material, for example, and may be provided by injecting p-type or n-type dopant. A gate insulating layer 32 is disposed on a top surface of the active layer 41. The gate electrode 42 is disposed on a top surface of the gate insulating layer 32 to correspond to the active layer 41. The first capacitor electrode 51 and the gate electrode 42 are disposed in and/or on the same layer, and include the same material.

An interlayer dielectric 33 is provided to cover the gate electrode 42 and the source/drain electrodes 43 are disposed on the interlayer dielectric 33, and contact with a certain area of the active layer 41. The second capacitor electrode 52 and the source/drain electrodes 43 are disposed in and/or on the same layer, and include the same material.

A passivation layer 34 is provided to cover the source/drain electrodes 43, and an additional insulating layer may be further provided to planarize the TFT 40.

The first electrode 61 is disposed on the passivation layer 34. The first electrode 61 may be provided to be electrically connected to any one of the source/drain electrodes 43. Also, a pixel defining layer 35 is provided to cover the first electrode 61. A certain opening 64 is defined in the pixel defining layer 35, and then the intermediate 63 including an organic emission layer is disposed on an area defined as the opening 64. The second electrode 62 is disposed on the intermediate layer 63.

An encapsulation layer 70 is disposed on the second electrode 62. The encapsulation layer 70 may include an organic material or an inorganic material and may have a structure provided by alternatively depositing the organic material and inorganic material.

The encapsulation layer 70 may be provided by using the vapor deposition apparatus 100 or 200 described above. That is, a desired layer may be provided by allowing the substrate 30 provided with the second electrode 62 to pass through the vapor deposition apparatus 100 or 200.

In an exemplary embodiment, referring to FIG. 6, the encapsulation layer 70 includes an inorganic layer 71 and an organic layer 72. The inorganic layer 71 includes a plurality of layers 71a, 71b and 71c, and the organic layer 72 includes a plurality of layers 72a, 72b and 72c. In this case, the plurality of layers 71a, 71b, and 71c of the inorganic layer 71 may be provided by using the vapor deposition apparatus 100 or 200.

However, the invention is not limited thereto. That is, other insulating layers of the organic light emitting display apparatus 10 such as the buffer layer 31, the gate insulating layer 32, the interlayer dielectric 33, the passivation layer 34 and the pixel defining layer 35 may be provided by using the vapor deposition apparatus 100 or 200.

Also, other various thin films such as the active layer 41, the gate electrode 42, the source/drain electrodes 43, the first electrode 61, the intermediate layer 63 and the second electrode 62 may be provided by using the vapor deposition apparatus 100 or 200.

As described above, when the vapor deposition apparatuses 100 or 200 is used, electric properties and image quality of the OLED apparatus 10 may be enhanced by improving the properties of deposited films disposed on the OLED apparatus 10.

As described above, according to the one or more of the above exemplary embodiments of the invention, a raw gas is uniformly injected onto a substrate and an exhaust gas is uniformly sucked, thereby improving the process efficiency of a vapor deposition apparatus.

Also, since an injection unit injecting the raw gas and a suction unit sucking the exhaust gas may have the same configuration, a configuration of the vapor deposition apparatus may be simplified.

Also, since impurities and the like are filtered by a filter unit while injecting the raw gas and sucking the exhaust gas and the filter unit is detachably coupled with the vapor deposition apparatus, the vapor deposition apparatus may be easily maintained and repaired.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

While one or more exemplary embodiments of the invention have been described with reference to the accompanying figures, it will be understood by those of ordinary skill in the art that various changes in the form and details may be made therein without departing from the spirit and scope of the invention as defined by the following claims.

What is claimed is:

1. A vapor deposition apparatus comprising:
a first injection unit through which a first raw gas is injected in a first direction; and
a first filter unit which is mounted in the first injection unit and comprises:
a plurality of plates separated from one another in the first direction and disposed in parallel to one another,
wherein holes are defined in each of the plurality of plates which is detachably coupled in the first filter unit.

2. The vapor deposition apparatus of claim 1, wherein a number of the holes defined in the plurality of plates increases in the first direction.

3. The vapor deposition apparatus of claim 1, wherein a size of the holes defined in the plurality of plates decreases in the first direction.

4. The vapor deposition apparatus of claim 1, further comprising a second injection unit through which a second raw gas is injected in the first direction,
wherein a plasma generator is disposed in a plasma generation part of the second injection unit,
a corresponding surface of a body of the vapor deposition apparatus surrounds the plasma generator, and
a plasma generation space is provided between the plasma generator and the corresponding surface of the body of the vapor deposition apparatus.

5. The vapor deposition apparatus of claim 4, further comprising an exhaust unit located between the first injection unit and the second injection unit,
wherein the first filter unit is mounted in the exhaust unit.

6. The vapor deposition apparatus of claim 5, wherein the first injection unit and the exhaust unit have a same configuration.

7. The vapor deposition apparatus of claim 4, further comprising a supply part which supplies the second raw gas to the plasma generation space,
wherein a second filter unit is mounted in the second injection unit.

8. The vapor deposition apparatus of claim 7, wherein the first filter unit and the second filter unit have a same configuration.

9. The vapor deposition apparatus of claim 4, further comprising a purge unit between the first injection unit and the second injection unit.

10. A vapor deposition apparatus for providing a deposition film on a substrate, the vapor deposition apparatus comprising:
a first injection unit through which a first raw gas is injected in a first direction toward the substrate;
a purge unit through which a purge gas is injected in the first direction; and
an exhaust unit through which an exhaust gas is discharged in a second direction opposite the first direction,
wherein first filter units are respectively mounted in the first injection unit and the exhaust unit, and the first injection unit and the exhaust unit have a same configuration.

11. The vapor deposition apparatus of claim 10, wherein each of the first filter units comprises a plurality of plates disposed in the first direction in parallel to one another, and holes are defined in each of the plurality of plates.

12. The vapor deposition apparatus of claim 11, wherein the plurality of plates is arranged to be separated from one another, and
wherein a number of the holes defined in the plurality of plates increases in the first direction.

13. The vapor deposition apparatus of claim 12, wherein the number of the holes defined in the plurality of plates increases two or three times in the first direction.

14. The vapor deposition apparatus of claim 12, wherein a size of the holes defined in the plurality of plates decreases in the first direction.

15. The vapor deposition apparatus of claim 11, wherein each of the plurality of plates is detachably coupled in each of the first filter units.

16. The vapor deposition apparatus of claim 10, further comprising a second injection unit through which a second raw gas is injected in the second direction,
wherein the purge unit and the exhaust unit are disposed between the first injection unit and the second injection unit.

17. The vapor deposition apparatus of claim 16, wherein the second injection unit comprises a plasma generator in a plasma generation part of the second injection unit,
a corresponding surface of a body of the vapor deposition apparatus surrounds the plasma generator, and
a plasma generation space is provided between the plasma generator and the corresponding surface of the body of the vapor deposition apparatus.

18. The vapor deposition apparatus of claim 17, further comprising a supply part which supplies the second raw gas to the plasma generation space,
wherein a second filter unit is mounted on the second injection unit.

19. The vapor deposition apparatus of claim 18, wherein each of the first filter units and the second filter unit have a same configuration.

20. The vapor deposition apparatus of claim 10, wherein the substrate moves relative to the vapor deposition apparatus.
